(19) United States
(12) Patent Application Publication
(10) Pub. No.: US 2023/0095970 A1
(43) Pub. Date: Mar. 30, 2023

(54) METHODS FOR TREATING PHOTORESISTS WITH NON-METAL COMPOUNDS

(71) Applicant: Applied Materials, Inc., Santa Clara, CA (US)

(72) Inventors: Zhiyu HUANG, Sunnyvale, CA (US); Chi-I LANG, Cupertino, CA (US); Yung-chen LIN, Gardena, CA (US); Ho-yung HWANG, Cupertino, CA (US); Gabriela ALVA, Santa Clara, CA (US); Wayne R. FRENCH, San Jose, CA (US)

(21) Appl. No.: 17/893,000

(22) Filed: Aug. 22, 2022

Related U.S. Application Data
(60) Provisional application No. 63/248,828, filed on Sep. 27, 2021.

(51) Int. Cl. G03F 7/00; G03F 7/20; C23C 16/04; C23C 16/40; C23C 16/44

(52) U.S. Cl. CPC G03F 7/0035; G03F 7/2004; C23C 16/042; C23C 16/401; C23C 16/4408

(57) ABSTRACT

Embodiments of the present disclosure generally relate to methods for enhancing photoresist (PR) to have improved profile control. A method for treating a PR includes positioning a workpiece within a process region of a processing chamber, where the workpiece contains a patterned PR disposed on an underlayer, and treating the patterned PR by exposing the workpiece to a sequential infiltration synthesis (SIS) process to produce a treated patterned PR which is denser and harder than the patterned PR. The SIS process includes one or more infiltration cycles of exposing the patterned PR to a precursor containing silicon or boron, infiltrating the patterned PR with the precursor, purging to remove remnants of the precursor, exposing the patterned PR to an oxidizing agent, infiltrating the patterned PR with the oxidizing agent to produce oxide coating disposed on inner surfaces of the patterned PR, and purging to remove remnants of the oxidizing agent.

### CROSS-REFERENCE TO RELATED APPLICATIONS

This application claims benefit to U.S. Prov. Appl. No. 63/248,828, filed on Sep. 27, 2021, which is herein incorporated by reference.

### BACKGROUND

### Field

Embodiments of the present disclosure generally relate to photoresist technology, and more specifically, relate to methods for enhancing photoresist to have improved profile control.

### Description of the Related Art

Integrated circuits have evolved into complex devices that can include millions of components (e.g., transistors, capacitors and resistors) on a single chip. Photolithography may be used to form components on a chip. Generally the process of photolithography involves forming a photoresist layer on a substrate. The photoresist layer may be formed by, for example, spin-coating. The photoresist layer may include a resist resin and a photoacid generator. The photoacid generator, upon exposure to electromagnetic radiation in the subsequent exposure stage, alters the solubility of the photoresist in the development process. The electromagnetic radiation may have any suitable wavelength, such as a wavelength in the extreme ultra violet region, and can be from any suitable source, e.g., a 193 nm ArF laser, an electron beam, an ion beam, or other source. Excess solvent may then be removed in a pre-exposure bake process.

During an exposure stage, a photomask or reticle may be used to selectively expose certain regions of a photoresist layer disposed on the substrate to electromagnetic radiation. Other exposure methods may be maskless exposure methods. Exposure to light may decompose the photoacid generator, which generates acid and results in a latent acid image in the resist resin. After exposure, the substrate may be heated in a post-exposure bake process. During the post-exposure bake process, the acid generated by the photoacid generator reacts with the resist resin in the photoresist layer, changing the solubility of the resist of the photoresist layer during a subsequent development process.

After the post-exposure bake, the substrate and the photoresist layer are developed and rinsed. Subsequently, a patterned photoresist layer is then formed on the substrate. Openings are defined within the patterned photoresist layer, after the development and rinse processes, exposing the underlying target material for etching to transfer features onto a target material. Factors such as inaccurate control or low resolution of the lithography exposure process, or resilience of the patterned layer, may cause poor critical dimension of the patterned photoresist layer, resulting in unacceptable line width roughness (LWR). Large line width roughness (LWR) of the patterned photoresist layer may result in inaccurate feature transfer to the target material, which can eventually lead to premature device failure and yield loss.

One specific type of photoresist is extreme ultraviolet (EUV) photoresist. Often the EUV PR material contains metals incorporated into the film and/or can be treated with metal-containing additives. The metals can be or include aluminum, zirconium, hafnium, or tin, which usually become undesirable impurities within the PR material. It is desirable to have non-metal PR materials and treatments for EUV PR layers. Also, existing EUV PR materials have limited etch selectivity between the PR layer and the underlayer due the strength of the EUV RV materials. As such, it is desirable to prepare improved EUV PR material which are strengthened and have better etch selectivity between the PR layer and the underlayer over the existing EUV PR materials. Furthermore, existing EUV PR materials suffer from pattern transfer defects and moderate line edge roughness (LER) and line width roughness (LWR).

Therefore, there is a need for an improved method to prepare photoresist which overcomes these shortcomings.

### SUMMARY

Embodiments of the present disclosure generally relate to methods for enhancing photoresist (PR) to have improved profile control. In one or more embodiments, a method of treating a photoresist layer is provided and includes positioning a workpiece within a process region of a processing chamber, where the workpiece contains a patterned PR layer disposed on an underlayer, and treating the patterned PR layer by exposing the workpiece to a sequential infiltration synthesis (SIS) process to produce a treated patterned PR layer which is denser and harder than the patterned PR layer. In one or more examples, the SIS process includes one or more infiltration cycles of exposing the patterned PR layer to a precursor containing silicon or boron, infiltrating the patterned PR layer with the precursor via pores contained in the patterned PR layer, purging the process region to remove gaseous remnants containing the precursor, exposing the patterned PR layer to an oxidizing agent, infiltrating the patterned PR layer with the oxidizing agent via the pores contained in the patterned PR layer to produce oxide coating disposed on inner surfaces of the patterned PR layer, wherein the oxide coating contains silicon oxide or boron oxide, and purging the process region to remove gaseous remnants containing the oxidizing agent.

In some embodiments, a method of treating a photoresist layer is provided and includes positioning a workpiece within a process region of a processing chamber, where the workpiece contains a patterned PR layer disposed on an underlayer and treating the patterned PR layer by exposing the workpiece to a SIS process to produce a treated patterned PR layer which is denser and harder than the patterned PR layer. The SIS process includes one or more infiltration cycles of exposing the patterned PR layer to a silicon precursor, infiltrating the patterned PR layer with the silicon precursor via pores contained in the patterned PR layer, purging the process region to remove gaseous remnants containing the silicon precursor, exposing the patterned PR layer to an oxidizing agent, infiltrating the patterned PR layer with the oxidizing agent via the pores contained in the patterned PR layer to produce a silicon oxide coating disposed on inner surfaces of the patterned PR layer, and purging the process region to remove gaseous remnants containing the oxidizing agent.

In other embodiments, a method of treating a photoresist layer is provided and includes positioning a workpiece within a process region of a processing chamber, where the workpiece contains a patterned PR layer disposed on an underlayer and treating the patterned PR layer by exposing the workpiece to a SIS process to produce a treated patterned PR layer which is denser and harder than the patterned PR layer. The SIS process contains one or more infiltration cycles of exposing the patterned PR layer to a chlorosilane precursor, infiltrating the patterned PR layer with the chlorosilane precursor via pores contained in the patterned PR layer, purging the process region to remove gaseous remnants containing the chlorosilane precursor, exposing the patterned PR layer to an oxidizing agent, infiltrating the patterned PR layer with the oxidizing agent via the pores contained in the patterned PR layer to produce a silicon oxide coating disposed on inner surfaces of the patterned PR layer, and purging the process region to remove gaseous remnants containing the oxidizing agent.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIGS. 1A-1C depict a cross-sectional view of workpiece at different stages of a treatment process, as described and discussed in one or more embodiments herein.

To facilitate understanding, identical reference numerals have been used, where possible, to designate identical elements that are common to the Figures. It is contemplated that elements and features of one or more embodiments may be beneficially incorporated in other embodiments.

### DETAILED DESCRIPTION

According to the embodiments described and disclosed herein, an oxide coating containing silicon oxide or boron oxide, is formed or otherwise produced in patterned photoresist (PR) layer. A silicon or boron precursor is introduced into a process region of a processing chamber having a film stack disposed therein. The silicon or boron precursor can be or include one or more silicon precursors or one or more boron precursors. The film stack, in one example, includes one or more underlayer disposed on a substrate, and the patterned PR layer disposed on the underlayer. The film stack, and thus the patterned PR layer is heated, and the silicon or boron precursor is absorbed into the patterned PR layer. Subsequently, the process region is purged to remove gaseous remnants containing the silicon or boron precursor. Thereafter, the film stack is exposed to one or more oxidizing agents. The oxidizing agent is heated and absorbed into the patterned PR layer and oxidizes the absorbed silicon or boron precursor. Upon oxidation, the silicon or boron precursor forms an oxide coating in and on the patterned PR layer. Subsequently, the process region is purged to remove gaseous remnants containing the oxidizing agent.

In one or more examples, the silicon precursor a chlorosilane (e.g., tetrachlorosilane) that is introduced into the process region, and subsequently the process region is purged and pumped. Thereafter, the oxidizing agent (e.g., water) is introduced into the process region, and subsequently the process region is purged and pumped to conclude one infiltration cycle. In some embodiments, the treatment process includes a single infiltration cycle to treat the pattern PR layer. In other embodiments, the infiltration cycle can be repeated numerous times (e.g., 2 times to about 20 times) to treat the pattern PR layer. Beneficially, the treatment process enables the oxide coating to infiltrate into the patterned PR layer at a depth of about 20 nm and about 40 nm in some examples. Furthermore, the oxide coating is cross-linked throughout the entire thickness of patterned PR layer.

The treatment methods described and disclosed herein are independent of feature size. Advantageously, infiltration of the oxide coating into one or more of the underlayers can achieve a change in critical dimension of less than 1 nm, and the line width roughness is changed by less than 0.4 nm. Accordingly, the method of infiltration of the oxide coating into the material of the PR layer ensures that the oxide coating does not infiltrate into the underlayer, by controlling the properties of the patterned PR layer, including density, with respect to the properties of the underlayer. For example, the patterned PR layer can be selected from a low density carbonyl group material, and the underlayer selected from a high density material, such as silicon, germanium, gallium, or derivatives thereof, including each of the materials described and disclosed herein.

Embodiments of the present disclosure generally relate to methods for enhancing photoresists to have improved profile control. In one or more embodiments, a method of treating a PR layer is provided and includes positioning a workpiece within a process region of a processing chamber, where the workpiece contains a patterned PR layer disposed on an underlayer, and treating the patterned PR layer by exposing the workpiece to a sequential infiltration synthesis (SIS) process to produce a treated patterned PR layer which is denser and harder than the untreated or original patterned PR layer.

In one or more examples, the SIS process includes one or more infiltration cycles of exposing the patterned PR layer to a precursor containing silicon or boron, infiltrating the patterned PR layer with the precursor via pores contained in the patterned PR layer, purging the process region to remove gaseous remnants containing the precursor, exposing the patterned PR layer to an oxidizing agent, infiltrating the patterned PR layer with the oxidizing agent via the pores contained in the patterned PR layer to produce oxide coating disposed on inner surfaces of the patterned PR layer, wherein the oxide coating contains silicon oxide or boron oxide, and purging the process region to remove gaseous remnants containing the oxidizing agent.

Each of the infiltration cycles of the SIS process include a first segment of exposing and infiltrating by a precursor, a second segment of purging the process region to remove remaining gaseous precursor, a third segment of exposing and infiltrating by an oxidizing agent, and a fourth segment of purging the process region to remove remaining gaseous precursor. One or more carrier gases can be flowed into the process region along with the precursor and/or the oxidizing agent during the first and third segments, respectively, of the SIS process. One or more purge gases can be flowed into the process region which is also being evacuated during the second and fourth segments of the SIS process. The carrier gas and the purge gas can be the same composition or different compositions. Exemplary carrier gases and/or purge gases can be or include argon, helium, neon, nitrogen (N₂), hydrogen (H₂), or any combination thereof.

The process region of the processing chamber is the internal volume within the processing chamber. The process region and/or the internal volume of the processing chamber are maintained at and/or adjusted to one or more pressures below atmospheric or ambient pressure (e.g., less than 760 Torr) during the SIS process. The pressure of the process region and/or the internal volume of the processing chamber is at about 1 Torr, about 5 Torr, about 10 Torr, about 15 Torr, about 20 Torr, about 25 Torr, about 35 Torr, or about 50 Torr to about 80 Torr, about 100 Torr, about 150 Torr, about 200 Torr, about 250 Torr, about 300 Torr, about 350 Torr, about 400 Torr, about 450 Torr, about 500 Torr, or about 600 Torr during the SIS process. For example, the pressure of the process region and/or the internal volume of the processing chamber is at about 1 Torr to about 600 Torr, about 1 Torr to about 500 Torr, about 1 Torr to about 400 Torr, about 1 Torr to about 350 Torr, about 1 Torr to about 300 Torr, about 1 Torr to about 250 Torr, about 1 Torr to about 200 Torr, about 1 Torr to about 150 Torr, about 1 Torr to about 100 Torr, about 1 Torr to about 50 Torr, about 10 Torr to about 600 Torr, about 10 Torr to about 500 Torr, about 10 Torr to about 400 Torr, about 10 Torr to about 350 Torr, about 10 Torr to about 300 Torr, about 10 Torr to about 250 Torr, about 10 Torr to about 200 Torr, about 10 Torr to about 150 Torr, about 10 Torr to about 100 Torr, about 10 Torr to about 50 Torr, about 15 Torr to about 600 Torr, about 15 Torr to about 500 Torr, about 15 Torr to about 400 Torr, about 15 Torr to about 350 Torr, about 15 Torr to about 300 Torr, about 15 Torr to about 250 Torr, about 15 Torr to about 200 Torr, about 15 Torr to about 150 Torr, about 15 Torr to about 100 Torr, about 15 Torr to about 50 Torr, about 50 Torr to about 600 Torr, about 50 Torr to about 500 Torr, about 50 Torr to about 400 Torr, about 50 Torr to about 350 Torr, about 50 Torr to about 300 Torr, about 50 Torr to about 250 Torr, about 50 Torr to about 200 Torr, about 50 Torr to about 150 Torr, about 50 Torr to about 100 Torr, about 100 Torr to about 600 Torr, about 100 Torr to about 500 Torr, about 100 Torr to about 400 Torr, about 100 Torr to about 350 Torr, about 100 Torr to about 300 Torr, about 100 Torr to about 250 Torr, about 100 Torr to about 200 Torr, or about 100 Torr to about 150 Torr during the SIS process.

Each of the first segment and the third segment of the infiltration cycle can independently last about 20 seconds, about 30 seconds, about 35 seconds, about 40 seconds, or about 45 seconds to about 50 seconds, about 60 seconds, about 70 seconds, about 80 seconds, about 90 seconds, about 100 seconds, about 2 minutes, about 2.5 minutes, about 3 minutes, about 4 minutes, about 5 minutes, about 6 minutes, about 8 minutes, about 10 minutes, about 12 minutes, about 15 minutes, about 18 minutes, or about 20 minutes during the SIS process. For example, each of the first segment and the third segment of the infiltration cycle can independently last about 20 seconds to about 20 minutes, about 20 seconds to about 15 minutes, about 20 seconds to about 12 minutes, about 20 seconds to about 10 minutes, about 20 seconds to about 8 minutes, about 20 seconds to about 6 minutes, about 20 seconds to about 5 minutes, about 20 seconds to about 4 minutes, about 20 seconds to about 3 minutes, about 20 seconds to about 2.5 minutes, about 20 seconds to about 2 minutes, about 20 seconds to about 100 seconds, about 20 seconds to about 90 seconds, about 20 seconds to about 75 seconds, about 20 seconds to about 60 seconds, about 20 seconds to about 45 seconds, about 20 seconds to about 30 seconds, about 40 seconds to about 5 minutes, about 40 seconds to about 4 minutes, about 40 seconds to about 3 minutes, about 40 seconds to about 2.5 minutes, about 40 seconds to about 2 minutes, about 40 seconds to about 100 seconds, about 40 seconds to about 90 seconds, about 40 seconds to about 75 seconds, about 40 seconds to about 60 seconds, about 60 seconds to about 5 minutes, about 60 seconds to about 4 minutes, about 60 seconds to about 3 minutes, about 60 seconds to about 2.5 minutes, about 60 seconds to about 2 minutes, about 60 seconds to about 100 seconds, about 60 seconds to about 90 seconds, or about 60 seconds to about 75 seconds during the SIS process.

Each of the second segment and the fourth segment of the infiltration cycle can independently last about 20 seconds, about 30 seconds, about 35 seconds, about 40 seconds, or about 45 seconds to about 50 seconds, about 60 seconds, about 70 seconds, about 80 seconds, about 90 seconds, about 100 seconds, about 2 minutes, about 2.5 minutes, about 3 minutes, about 4 minutes, about 5 minutes, about 6 minutes, about 8 minutes, about 10 minutes, about 12 minutes, about 15 minutes, about 20 minutes, about 25 minutes, or about 30 minutes during the SIS process. For example, each of the second segment and the fourth segment of the infiltration cycle can independently last about 20 seconds to about 30 minutes, about 20 seconds to about 25 minutes, about 20 seconds to about 20 minutes, about 20 seconds to about 15 minutes, about 20 seconds to about 12 minutes, about 20 seconds to about 10 minutes, about 20 seconds to about 8 minutes, about 20 seconds to about 6 minutes, about 20 seconds to about 5 minutes, about 20 seconds to about 4 minutes, about 20 seconds to about 3 minutes, about 20 seconds to about 2.5 minutes, about 20 seconds to about 2 minutes, about 20 seconds to about 100 seconds, about 20 seconds to about 90 seconds, about 20 seconds to about 75 seconds, about 20 seconds to about 60 seconds, about 20 seconds to about 45 seconds, about 20 seconds to about 30 seconds, about 40 seconds to about 5 minutes, about 40 seconds to about 4 minutes, about 40 seconds to about 3 minutes, about 40 seconds to about 2.5 minutes, about 40 seconds to about 2 minutes, about 40 seconds to about 100 seconds, about 40 seconds to about 90 seconds, about 40 seconds to about 75 seconds, about 40 seconds to about 60 seconds, about 60 seconds to about 5 minutes, about 60 seconds to about 4 minutes, about 60 seconds to about 3 minutes, about 60 seconds to about 2.5 minutes, about 60 seconds to about 2 minutes, about 60 seconds to about 100 seconds, about 60 seconds to about 90 seconds, or about 60 seconds to about 75 seconds during the SIS process.

The infiltration cycle can be conducted once, twice, or multiple times during the SIS process. In some examples, the infiltration cycle is repeated in a range from 2 times, 3 times, 4 times, or 5 times to 6 times, 7 times, 8 times, 9 times, about 10 times, about 12 times, about 15 times, about 20 times, or more during the SIS process. For example, the infiltration cycle is repeated in a range from 2 times to about 20 times, 2 times to about 15 times, 2 times to about 10 times, 2 times to 8 times, 2 times to 5 times during the SIS process.

The precursor exposed to the PR layer can be one or more silicon precursors or one or more boron precursors. The oxidizing agent can be or include any compound or reagent which will oxidize the silicon precursor to produce silicon oxide or the boron precursor to produce boron oxide. The oxidizing agent can be or include water, ozone, oxygen plasma, oxygen radicals, oxygen (O₂), hydrogen peroxide, or any combination thereof.

In one or more embodiments, the precursor is or includes one or more silicon precursors and the oxide coating formed within the patterned PR layer is or includes silicon oxide. The silicon precursor can be or include one or more chlorosilane precursors, one or more alkoxysilanes, one or more silanols, one or more organosilanols, one or more aminoalkyl alkoxy silanes, or any combination thereof. In some examples, the silicon precursor is or contains hexachlorodisilane, tetrachlorosilane, trichlorosilane, dichlorosilane, chlorosilane, or any combination thereof. In other examples, the silicon precursor is or contains tetramethoxysilane (MEOS), tetraethoxysilane (TEOS), tetrapropoxysilane, or any combination thereof. In one or more examples, the silicon precursor is or contains a silanol and/or an organosilanol having the chemical formula of (RO)₄₋ₙSi(OH)ₙ, where each R is independently methyl, ethyl, propyl, butyl, or pentyl and n is 1, 2, 3, or 4. Exemplary silanols and/or organosilanols can be trimethylsilanol, triethylsilanol, tripropylsilanol, tributylsilanol, or any combination thereof. In some examples, the silicon precursor is or contains an aminoalkyl alkoxy silane having the chemical formula of (R″O)₄₋ₙSi(R′NH₂)ₙ, where each R′ is independently methylene, ethylene, propylene, or butylene, each R″ is independently methylene, ethylene, propylene, or butylene, and n is 1, 2, or 3. Exemplary aminoalkyl alkoxy silane can be (3-aminopropyl)trimethoxysilane, (3-aminopropyl)triethoxysilane (APTES), (3-aminopropyl)triproxysilane, or any combination thereof.

In one or more examples, the silicon precursor is or contains one or more chlorosilanes and the oxidizing agent is or includes water. In other examples, the silicon precursor is or contains one or more alkoxysilanes or aminoalkyl alkoxy silanes and the oxidizing agent is or contains ozone or oxygen plasma.

In other embodiments, the precursor is or includes one or more boron precursors and the oxide coating formed within the patterned PR layer is or includes boron oxide. The boron precursor can be one or more boron halides, one or more alkyl boron halides, one or more alkylboranes, complexes thereof, or any combination thereof. In some examples, the precursor can be or include one or more boron halides. Exemplary boron halides can be or include boron trichloride, boron dichloride, boron chloride, boron tribromide, complexes thereof, or any combination thereof. In one or more examples, the oxide coating contains boron oxide, the precursor contains a boron trichloride, and the oxidizing agent contains water.

In some embodiments, the treatment method includes exposing the patterned PR layer to one or more catalysts during the SIS process. The catalyst can be introduced into the process region and exposed to the patterned PR layer at any segment of the of the infiltration cycle. In some embodiments, additional segments can be added to the infiltration cycle to include the catalyst. In some examples, the catalyst is introduced at the same time as the silicon precursor or the boron precursor. In other examples, the catalyst is introduced at the same time as the oxidizing agent. The catalyst can be or include one or more pnictogen hydrides or one or more organometallic compounds. The catalyst can be or include one or more nitrogen hydrides, one or more alkyl amines, one or more phosphorous hydrides, one or more alkyl phosphines, one or more aluminum alkyls, one or more of pyridines and/or derivatives thereof, complexes thereof, or any combination thereof. Exemplary catalyst can be or include ammonia, hydrazine, phosphine, trimethylaluminum, triethylaluminum, tripropylaluminum, tributylaluminum, trimethylamine, triethyl amine, pyridine, complexes thereof, or any combination thereof.

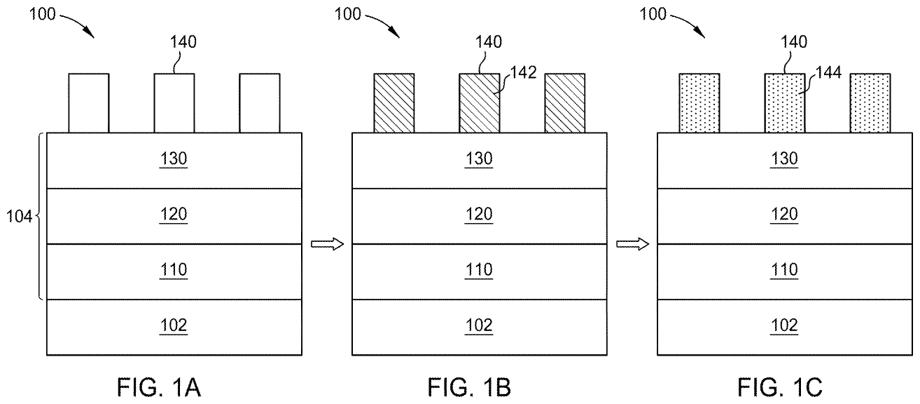

FIGS. 1A-1C depict a cross-sectional view of a workpiece 100 at different stages of a process for treating a photoresist layer, as described and discussed in one or more embodiments herein. FIG. 1A depicts the workpiece 100 containing a stack 104 disposed on a substrate 102 and a patterned photoresist (PR) layer 140 disposed on the stack 104. The stack 104 can include two, three, four, or more layers of different types of materials. As shown in FIG. 1A, the stack 104 contains an under layer 110 disposed on the substrate 102, a hard mask layer 120 disposed the under layer 110, and an anti-reflective (or anti-reflection) coating (ARC) 130 disposed on the hard mask layer 120. The hard mask layer 120 is disposed between the under layer 110 and the ARC 130.

The substrate 102 can be made of or include one or more materials, such as silicon, silicon oxide, doped silicon, silicon germanium, germanium, gallium arsenide, glass, sapphire, and any other materials, such as metals, metal nitrides, metal alloys, and other conductive or semi-conductive materials, depending on the application. The substrate 102, or surface thereof, can also be made of dielectric materials such as silicon dioxide, silicon nitride, one or more organosilicates, carbon-doped silicon oxide materials, carbon-doped silicon nitride materials, other nitrides, or any combination thereof. The substrate 102 can be any geometry, such as round, square, or rectangular. In some examples, the substrate 102 is round and has a diameter of 200 mm, 250 mm, 300 mm, or 450 mm.

The under layer 110 can be or include an oxide layer or a silicon-containing layer, such as silicon oxide, amorphous silicon, a tetraethoxysilane (TEOS) layer, or any combination thereof. The under layer 110 can be formed or otherwise produced by chemical vapor deposition (CVD) or plasma-enhanced CVD (PECVD). The hard mask layer 120 can be or include carbon, amorphous carbon, spin-on carbon (SOC), spin-on glass (SOG), silicon oxide, silicon oxynitride, dopants thereof, or any combination thereof. The hard mask layer 120 can be formed or otherwise produced by CVD, PECVD, or spin-on process. The ARC 130 can be or include a silicon-containing ARC (SiARC), bottom ARC (BARC), dielectric ARC (DARC), other ARC layers, or any combination thereof. In one or more examples, the hard mask layer 120 can be or include an advanced patterning film (APF) and the ARC 130 can be or include one or more silicon materials.

The patterned PR layer 140 can be or include a mask or other patterned layer developed, prepared, or otherwise produced by one or multiple processes. In some examples, the patterned PR layer 140 is prepared by a lithography process, such as by an extreme ultraviolet (EUV) lithography process. The patterned PR layer 140 is porous and can have pores throughout the material including all surfaces of the patterned PR layer 140. As shown in FIG. 1A, the patterned PR layer 140 has been formed, but remains untreated relative to the SIS process as described and discussed herein.

FIG. 1B depicts the workpiece 100 having the patterned PR layer 140 containing an infiltrated coating 142 of the precursor, such as the silicon precursor or the boron precursor. The infiltrated coating 142 of the precursor coats or otherwise is disposed throughout the inner surfaces of the patterned PR layer 140. The precursor penetrates through the pores contained throughout the patterned PR layer 140. The infiltrated coating 142 contains absorbed and/or condensed amounts of the precursor, such as during the first segment of the SIS process. Thereafter, the process region of the processing chamber can be purged to remove excess or remaining precursor within the process region during the second segment of the SIS process.

FIG. 1C depicts the workpiece 100 having the patterned PR layer 140 containing an oxide coating 144 formed from the infiltrated coating 142. During the third segment of the SIS process, the infiltrated coating 142 is oxidized by being exposed to an oxidizing agent to form the oxide coating 144, such as a coating containing silicon oxide or boron oxide depending on which type of precursor was used in the first segment of the SIS process. Thereafter, the process region of the processing chamber can be purged to remove excess or remaining precursor within the process region during the fourth segment of the SIS process. The treated patterned PR layer 140 containing the oxide coating 144 shown in FIG. 1C is denser and harder than the untreated patterned PR layer 140 shown in FIG. 1A.

Most traditional chemical vapor deposition (CVD) chambers or atomic layer deposition (ALD) chambers can be used as the processing chamber suitable for performing the SIS process described and discussed herein. One example of the processing chamber that may be adapted to benefit from the SIS process is a CENTRIS® Sym3™ etching processing chamber, commercially available from Applied Materials, Inc. An example of a tool or system that benefit from the SIS process is the Centura® system or Endura® system with an iSprint™ ALD/CVD SSW chamber, commercially available from Applied Materials, Inc.

Embodiments of the present disclosure further relate to any one or more of the following examples 1-37:

1. A method of treating a photoresist layer, comprising: positioning a workpiece within a process region of a processing chamber, wherein the workpiece comprises a patterned photoresist layer disposed on an underlayer; and treating the patterned photoresist layer by exposing the workpiece to a sequential infiltration synthesis (SIS) process to produce a treated patterned photoresist layer which is denser and harder than the patterned photoresist layer, wherein the SIS process comprises one or more infiltration cycles of: exposing the patterned photoresist layer to a silicon precursor; infiltrating the patterned photoresist layer with the silicon precursor via pores contained in the patterned photoresist layer; purging the process region to remove gaseous remnants containing the silicon precursor; exposing the patterned photoresist layer to an oxidizing agent; infiltrating the patterned photoresist layer with the oxidizing agent via the pores contained in the patterned photoresist layer to produce a silicon oxide coating disposed on inner surfaces of the patterned photoresist layer; and purging the process region to remove gaseous remnants containing the oxidizing agent.

2. A method of treating a photoresist layer, comprising: positioning a workpiece within a process region of a processing chamber, wherein the workpiece comprises a patterned photoresist layer disposed on an underlayer; and treating the patterned photoresist layer by exposing the workpiece to a SIS process to produce a treated patterned photoresist layer which is denser and harder than the patterned photoresist layer, wherein the SIS process comprises one or more infiltration cycles of: exposing the patterned photoresist layer to a chlorosilane precursor; infiltrating the patterned photoresist layer with the chlorosilane precursor via pores contained in the patterned photoresist layer; purging the process region to remove gaseous remnants containing the chlorosilane precursor; exposing the patterned photoresist layer to an oxidizing agent; infiltrating the patterned photoresist layer with the oxidizing agent via the pores contained in the patterned photoresist layer to produce a silicon oxide coating disposed on inner surfaces of the patterned photoresist layer; and purging the process region to remove gaseous remnants containing the oxidizing agent.

3. The method according to example 1 or 2, wherein the underlayer comprises an anti-reflective coating (ARC).

4. The method according to any one of examples 1-3, wherein the workpiece comprises a stack disposed on a substrate, wherein the treated patterned photoresist layer is disposed on the stack, and wherein the stack comprises a hard mask layer disposed between an under layer and an ARC.

5. The method according to any one of examples 1-4, wherein the patterned photoresist layer is produced by an extreme ultraviolet (EUV) lithography process.

6. The method according to any one of examples 1-5 wherein the silicon precursor comprises a chlorosilane precursor, an alkoxysilane, an aminoalkyl alkoxy silane, or any combination thereof.

7. The method according to any one of examples 1-6, wherein the silicon precursor comprises hexachlorodisilane, tetrachlorosilane, trichlorosilane, dichlorosilane, chlorosilane, or any combination thereof.

8. The method according to any one of examples 1-7, wherein the silicon precursor comprises tetramethoxysilane (MEOS), tetraethoxysilane (TEOS), tetrapropoxysilane, or any combination thereof.

9. The method according to any one of examples 1-8, wherein the silicon precursor comprises an aminoalkyl alkoxy silane having the chemical formula of (R″O)₄₋ₙSi(R′NH₂)ₙ, wherein each R′ is independently methylene, ethylene, propylene, or butylene, each R″ is independently methylene, ethylene, propylene, or butylene, and n is 1, 2, or 3.

10. The method according to any one of examples 1-9, wherein the silicon precursor comprises (3-aminopropyl)trimethoxysilane, (3-aminopropyl)triethoxysilane (APTES), (3-aminopropyl)triproxysilane, or any combination thereof.

11. The method according to any one of examples 1-10, wherein the silicon precursor comprises a chlorosilane and the oxidizing agent comprises water.

12. The method according to any one of examples 1-11, wherein the silicon precursor comprises an alkoxysilane, or an aminoalkyl alkoxy silane and the oxidizing agent comprises ozone or oxygen plasma.

13. The method according to any one of examples 1-12, further comprising exposing the patterned photoresist layer to a catalyst during the SIS process.

14. The according to example 13, wherein the catalyst comprises ammonia, hydrazine, or trimethylaluminum.

15. The method according to any one of examples 1-14, wherein the infiltration cycle is repeated 2 times to about 10 times during the SIS process.

16. A method of treating a photoresist layer, comprising: positioning a workpiece within a process region of a processing chamber, wherein the workpiece comprises a patterned photoresist layer disposed on an underlayer; and treating the patterned photoresist layer by exposing the workpiece to a sequential infiltration synthesis (SIS) process to produce a treated patterned photoresist layer which is denser and harder than the patterned photoresist layer, wherein the SIS process comprises one or more infiltration cycles of: exposing the patterned photoresist layer to a precursor comprising silicon or boron; infiltrating the patterned photoresist layer with the precursor via pores contained in the patterned photoresist layer; purging the process region to remove gaseous remnants containing the precursor; exposing the patterned photoresist layer to an oxidizing agent; infiltrating the patterned photoresist layer with the oxidizing agent via the pores contained in the patterned photoresist layer to produce oxide coating disposed on inner surfaces of the patterned photoresist layer, wherein the oxide coating comprises silicon oxide or boron oxide; and purging the process region to remove gaseous remnants containing the oxidizing agent.

17. The method according to example 16, wherein the precursor comprises a boron halide.

18. The method according example 16 or 17, wherein the oxide coating comprises boron oxide, the precursor comprises a boron trichloride, and the oxidizing agent comprises water.

19. The method according to any one of examples 16-18, wherein the precursor comprises a chlorosilane precursor, an alkoxysilane, an aminoalkyl alkoxy silane, or any combination thereof.

20. The method according to any one of examples 16-19, wherein the precursor comprises hexachlorodisilane, tetrachlorosilane, trichlorosilane, dichlorosilane, chlorosilane, or any combination thereof.

21. The method according to any one of examples 16-20, wherein the precursor comprises tetramethoxysilane (MEOS), tetraethoxysilane (TEOS), tetrapropoxysilane, or any combination thereof.

22. The method according to any one of examples 16-21, wherein the precursor comprises an aminoalkyl alkoxy silane having the chemical formula of (R″O)₄₋ₙSi(R′NH₂)ₙ, wherein each R′ is independently methylene, ethylene, propylene, or butylene, each R″ is independently methylene, ethylene, propylene, or butylene, and n is 1, 2, or 3.

23. The method according to any one of examples 16-22, wherein the precursor comprises (3-aminopropyl)trimethoxysilane, (3-aminopropyl)triethoxysilane (APTES), (3-aminopropyl)triproxysilane, or any combination thereof.

24. The method according to any one of examples 16-23, wherein the precursor comprises a chlorosilane and the oxidizing agent comprises water.

25. The method according to any one of examples 16-24, wherein the precursor comprises an alkoxysilane, or an aminoalkyl alkoxy silane and the oxidizing agent comprises ozone or oxygen plasma.

26. The method according to any one of examples 16-25, further comprising exposing the patterned photoresist layer to a catalyst during the SIS process.

27. The method according to example 26, wherein the catalyst comprises ammonia, hydrazine, or trimethylaluminum.

28. The method according to any one of examples 16-27, wherein the infiltration cycle is repeated 2 times to about 10 times during the SIS process.

29. The method according to any one of examples 16-28, wherein exposing and infiltrating the patterned photoresist layer to the precursor lasts for about 20 seconds to about 5 minutes.

30. The method according to any one of examples 16-29, wherein exposing and infiltrating the patterned photoresist layer to the precursor lasts for about 30 seconds to about 2 minutes.

31. The method according to any one of examples 16-30, wherein exposing and infiltrating the patterned photoresist layer to the oxidizing agent lasts for about 20 seconds to about 5 minutes.

32. The method according to any one of examples 16-31, wherein exposing and infiltrating the patterned photoresist layer to the oxidizing agent lasts for about 30 seconds to about 2 minutes.

33. The method according to any one of examples 16-32, wherein purging the process region to remove gaseous remnants containing the precursor or the oxidizing agent lasts for about 20 seconds to about 5 minutes.

34. The method according to any one of examples 16-33, wherein purging the process region to remove gaseous remnants containing the precursor or the oxidizing agent lasts for about 30 seconds to about 2 minutes.

35. The method according to any one of examples 16-34, wherein the underlayer comprises an ARC.

36. The method according to any one of examples 16-35, wherein the workpiece comprises a stack disposed on a substrate, wherein the treated patterned photoresist layer is disposed on the stack, and wherein the stack comprises a hard mask layer disposed between an under layer and an ARC.

37. The method according to any one of examples 16-36, wherein the patterned photoresist layer is produced by an EUV lithography process.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise, whenever a composition, an element, or a group of elements is preceded with the transitional phrase “comprising”, it is understood that the same composition or group of elements with transitional phrases “consisting essentially of”, “consisting of”, “selected from the group of consisting of”, or “is” preceding the recitation of the composition, element, or elements and vice versa, are contemplated. As used herein, the term “about” refers to a +/−10% variation from the nominal value. It is to be understood that such a variation can be included in any value provided herein.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

What is claimed is:

1. A method of treating a photoresist layer, comprising:
positioning a workpiece within a process region of a processing chamber, wherein the workpiece comprises a patterned photoresist layer disposed on an underlayer; and
treating the patterned photoresist layer by exposing the workpiece to a sequential infiltration synthesis (SIS) process to produce a treated patterned photoresist layer which is denser and harder than the patterned photoresist layer, wherein the SIS process comprises one or more infiltration cycles of:
exposing the patterned photoresist layer to a precursor comprising silicon or boron;
infiltrating the patterned photoresist layer with the precursor via pores contained in the patterned photoresist layer;
purging the process region to remove gaseous remnants containing the precursor;
exposing the patterned photoresist layer to an oxidizing agent;
infiltrating the patterned photoresist layer with the oxidizing agent via the pores contained in the patterned photoresist layer to produce oxide coating disposed on inner surfaces of the patterned photoresist layer, wherein the oxide coating comprises silicon oxide or boron oxide; and
purging the process region to remove gaseous remnants containing the oxidizing agent.

2. The method of claim 1, wherein the precursor comprises a boron halide.

3. The method of claim 1, wherein the oxide coating comprises boron oxide, the precursor comprises a boron trichloride, and the oxidizing agent comprises water.

4. The method of claim 1, wherein the precursor comprises a chlorosilane precursor, an alkoxysilane, an aminoalkyl alkoxy silane, or any combination thereof.

5. The method of claim 1, wherein the precursor comprises hexachlorodisilane, tetrachlorosilane, trichlorosilane, dichlorosilane, chlorosilane, or any combination thereof.

6. The method of claim 1, wherein the precursor comprises tetramethoxysilane (MEOS), tetraethoxysilane (TEOS), tetrapropoxysilane, or any combination thereof.

7. The method of claim 1, wherein the precursor comprises an aminoalkyl alkoxy silane having the chemical formula of (R″O)₄₋ₙSi(R′NH₂)ₙ, wherein each R′ is independently methylene, ethylene, propylene, or butylene, each R″ is independently methylene, ethylene, propylene, or butylene, and n is 1, 2, or 3.

8. The method of claim 1, wherein the precursor comprises (3-aminopropyl)trimethoxysilane, (3-aminopropyl)triethoxysilane (APTES), (3-aminopropyl)triproxysilane, or any combination thereof.

9. The method of claim 1, wherein the precursor comprises a chlorosilane and the oxidizing agent comprises water.

10. The method of claim 1, wherein the precursor comprises an alkoxysilane, or an aminoalkyl alkoxy silane and the oxidizing agent comprises ozone or oxygen plasma.

11. The method of claim 1, further comprising exposing the patterned photoresist layer to a catalyst during the SIS process.

12. The method of claim 11, wherein the catalyst comprises ammonia, hydrazine, or trimethylaluminum.

13. The method of claim 1, wherein the infiltration cycle is repeated 2 times to about 10 times during the SIS process.

14. The method of claim 1, wherein:
exposing and infiltrating the patterned photoresist layer to the precursor lasts for about 20 seconds to about 5 minutes;
exposing and infiltrating the patterned photoresist layer to the oxidizing agent lasts for about 20 seconds to about 5 minutes; and
purging the process region to remove gaseous remnants containing the precursor or the oxidizing agent lasts for about 20 seconds to about 5 minutes.

15. The method of claim 1, wherein the underlayer comprises an anti-reflective coating (ARC).

16. The method of claim 1, wherein the workpiece comprises a stack disposed on a substrate, wherein the treated patterned photoresist layer is disposed on the stack, and wherein the stack comprises a hard mask layer disposed between an under layer and an anti-reflective coating (ARC).

17. The method of claim 1, wherein the patterned photoresist layer is produced by an extreme ultraviolet (EUV) lithography process.

18. A method of treating a photoresist layer, comprising:
positioning a workpiece within a process region of a processing chamber, wherein the workpiece comprises a patterned photoresist layer disposed on an underlayer; and
treating the patterned photoresist layer by exposing the workpiece to a sequential infiltration synthesis (SIS) process to produce a treated patterned photoresist layer which is denser and harder than the patterned photoresist layer, wherein the SIS process comprises one or more infiltration cycles of:
exposing the patterned photoresist layer to a silicon precursor;
infiltrating the patterned photoresist layer with the silicon precursor via pores contained in the patterned photoresist layer;
purging the process region to remove gaseous remnants containing the silicon precursor;
exposing the patterned photoresist layer to an oxidizing agent;
infiltrating the patterned photoresist layer with the oxidizing agent via the pores contained in the patterned photoresist layer to produce a silicon oxide coating disposed on inner surfaces of the patterned photoresist layer; and
purging the process region to remove gaseous remnants containing the oxidizing agent.

19. The method of claim 18, wherein:
the silicon precursor comprises tetramethoxysilane (MEOS), tetraethoxysilane (TEOS), tetrapropoxysilane, or any combination thereof; or
the silicon precursor comprises an aminoalkyl alkoxy silane having the chemical formula of (R″O)₄₋ₙSi(R′NH₂)ₙ, wherein each R′ is independently methylene, ethylene, propylene, or butylene, each R″ is independently methylene, ethylene, propylene, or butylene, and n is 1, 2, or 3.

20. A method of treating a photoresist layer, comprising:
positioning a workpiece within a process region of a processing chamber, wherein the workpiece comprises a patterned photoresist layer disposed on an underlayer; and
treating the patterned photoresist layer by exposing the workpiece to a sequential infiltration synthesis (SIS) process to produce a treated patterned photoresist layer which is denser and harder than the patterned photoresist layer, wherein the SIS process comprises one or more infiltration cycles of:
exposing the patterned photoresist layer to a chlorosilane precursor;
infiltrating the patterned photoresist layer with the chlorosilane precursor via pores contained in the patterned photoresist layer;
purging the process region to remove gaseous remnants containing the chlorosilane precursor;
exposing the patterned photoresist layer to an oxidizing agent;
infiltrating the patterned photoresist layer with the oxidizing agent via the pores contained in the patterned photoresist layer to produce a silicon oxide coating disposed on inner surfaces of the patterned photoresist layer; and
purging the process region to remove gaseous remnants containing the oxidizing agent.
